(19) United States
(12) Patent Application Publication
(10) Pub. No.: US 2013/0161178 A1
(43) Pub. Date: Jun. 27, 2013

(54) TOUCH PANEL AND METHOD FOR MANUFACTURING THE SAME

(71) Applicants: Seul Gi Kim, Gyunggi-do (KR); Jae Hun Kim, Gyunggi-do (KR); Young Woo Lee, Gyunggi-do (KR); Jung Ryoul Yim, Gyunggi-do (KR); Kyu Sang Lee, Gyunggi-do (KR); Choong Hee Lee, Gyunggi-do (KR); Jin Uk Lee, Gyunggi-do (KR)

(72) Inventors: Seul Gi Kim, Gyunggi-do (KR); Jae Hun Kim, Gyunggi-do (KR); Young Woo Lee, Gyunggi-do (KR); Jung Ryoul Yim, Gyunggi-do (KR); Kyu Sang Lee, Gyunggi-do (KR); Choong Hee Lee, Gyunggi-do (KR); Jin Uk Lee, Gyunggi-do (KR)

(73) Assignee: SAMSUNG ELECTRO-MECHANICS CO., LTD., Gyunggi-do (KR)

(21) Appl. No.: 13/458,707

(22) Filed: Apr. 27, 2012

(30) Foreign Application Priority Data
Dec. 21, 2011 (KR) 1020110139324
Dec. 21, 2011 (KR) 1020110139325

(51) Int. Cl. H03K 17/975; G03F 7/20

(52) U.S. Cl. 200/600; 430/319

(57) ABSTRACT

Disclosed herein are a touch panel and a method for manufacturing the same. A touch panel 100 according to the preferred embodiment of the present invention is configured to include: a window 110 that is a support disposed at an outermost side; a first electrode pattern 120 containing silver formed by selectively exposing/developing a silver salt emulsion layer 150 and formed on one surface of the window 110 as a fine pattern; a second pattern 130 containing silver formed by selectively exposing/developing the silver salt emulsion layer 150 and formed on the other surface of the window 110 as a fine pattern; and an optical filter layer 140 formed at least one of between one surface of the window 110 and the first electrode pattern 120 and between the other surface of the window 110 and the second electrode pattern 130 to selectively block light.

### CROSS REFERENCE TO RELATED APPLICATION

This application claims the benefit of Korean Patent Application No. 10-2011-0139325, filed on Dec. 21, 2011, entitled “Method for Manufacturing Touch Panel”, Korean Patent Application No. 10-2011-0139324, filed on Dec. 21, 2011, and “Touch Panel”, which are hereby incorporated by reference in their entireties into this application.

### BACKGROUND OF THE INVENTION

1. Technical Field

The present invention relates to a touch panel and a method for manufacturing the same.

2. Description of the Related Art

With the development of computers using a digital technology, devices assisting computers have also been developed, and personal computers, portable transmitters and other personal information processors execute processing of text and graphics using a variety of input devices such as a keyboard and a mouse.

While the rapid advancement of an information-oriented society has been widening the use of computers more and more, it is difficult to efficiently operate products using only a keyboard and mouse currently serving as an input device. Therefore, the necessity for a device that is simple, has minimal malfunction, and is capable of easily inputting information has increased.

In addition, current techniques for input devices have progressed toward techniques related to high reliability, durability, innovation, designing and processing beyond the level of satisfying general functions. To this end, a touch panel has been developed as an input device capable of inputting information such as text, graphics, or the like.

This touch panel is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow a user to select desired information while viewing the image display device.

Meanwhile, the touch panel is classified into a resistive type touch panel, a capacitive type touch panel, an electromagnetic type touch panel, a surface acoustic wave (SAW) type touch panel, and an infrared type touch panel. These various types of touch panels are adapted for electronic products in consideration of a signal amplification problem, a resolution difference, a level of difficulty of designing and processing technologies, optical characteristics, electrical characteristics, mechanical characteristics, resistance to an environment, input characteristics, durability, and economic efficiency. Currently, the resistive type touch panel and the capacitive type touch panel have been prominently used in a wide range of fields.

In this touch panel, the electrode patterns are generally made of indium tin oxide (ITO). However, the ITO has low electrical conductivity, is expensive since indium used as a raw material thereof is a rare earth metal. In addition, the indium is expected to be depleted within the next decade, such that it may not be smoothly supplied. In addition, the electrode patterns made of ITO may have an easy brittle fracture characteristic and as a result, the durability thereof may be degraded.

For this reason, research into a technology of forming electrode patterns using a metal as disclosed in Korean Patent Laid-Open Publication No. 10-2010-0091497 has been actively conducted. However, a method for forming electrode patterns that may be commercialized by satisfying both of the electric conductivity and durability while using metal has not been developed.

### SUMMARY OF THE INVENTION

The present invention has been made in an effort to provide a touch panel having excellent electric conductivity while replacing ITO by forming electrode patterns containing silver by exposing/developing silver salt emulsion layers and a method for manufacturing the same.

According to a preferred embodiment of the present invention, there is provided a touch panel, including: a window that is a support disposed on an outermost side; first electrode patterns containing silver formed by selectively exposing/developing silver salt emulsion layers and formed on one surface of the window as a fine pattern; second electrode patterns containing silver formed by selectively exposing/developing silver salt emulsion layers and formed on the other surface of the window as a fine pattern; optical filter layers formed in at least one of between one surface of the window and the first electrode patterns and the other surface of the window and the second electrode patterns to selectively block light.

The touch panel may further include a protective layer covering the first electrode patterns.

The protective layer may be a hard coating layer, an optical clear adhesive, or an AR coating layer.

The hard coating layer may be made of acrylic, epoxy, urethane, or a combination thereof

The touch panel may further include: first wirings formed on one surface of the window and connected with the first electrode patterns; and second wirings formed on the other surface of the window and connected with the second electrode patterns.

The first wirings may contain silver formed by selectively exposing/developing the silver salt emulsion layers and may be integrally formed with the first electrode patterns, and the second wirings may contain silver formed by selectively exposing/developing the silver salt emulsion layers and may be integrally formed with the second electrode patterns.

The touch panel may further include: a control unit disposed on the window, wherein the first wirings and the second wirings are connected with the control unit.

The control unit may include: a first control unit disposed on one surface of the window; and a second control unit disposed on the other surface of the window, wherein the first wirings are connected with the first control unit and the second wirings are connected with the second control unit.

The touch panel may further include a printing part covering the first wirings.

The silver salt emulsion layers may include a silver salt and a binder.

The silver salt may be silver halide.

The optical filter layers may block an ultraviolet ray.

The optical filter layers may block an I-line, an H-line, or a G-line of the ultraviolet ray.

The optical filter layers may be made of UV blocking inorganic materials.

The optical filter layers may be made of UV blocking organic materials.

The silver salt emulsion layers may be exposed by using a proximity exposing device or a contact exposing device.

Sheet resistance of the first electrode pattern or sheet resistance of the second electrode pattern may be set to be 150 Ω/□ or less.

Sheet resistance of the first electrode pattern or sheet resistance of the second electrode pattern may be set to be 0.1 to 50 Ω/□.

A line width of the fine pattern of the first electrode pattern and a line width of the fine pattern of the second electrode pattern may be set to be 3 to 7 μm.

Transmittance of the touch panel may be set to be 85% or more.

An aperture ratio of the first electrode pattern or an aperture ratio of the second electrode pattern may be set to be 95% or more.

A thickness of the first electrode pattern or a thickness of the second electrode pattern may be set to be 2 μm or less.

A line width of the first wiring or a line width of the second wiring may be set to be 50 μm or less.

A pitch between the first wirings or a pitch between the second wirings may be set to be 50 μm or less.

According to another preferred embodiment of the present invention, there is provided a method for manufacturing a touch panel, including: (A) forming optical filter layer(s) on one surface or both surfaces of a window that is a support disposed on an outermost side so as to selectively block light; (B) forming a silver salt emulsion layer on the optical filter layer and the other surface of the window when the optical filter layer is formed on one surface of the window and forming silver salt emulsion layers on the optical filter layers when the optical filter layers are formed on both surfaces of the window; and (C) forming first electrode patterns and second electrode patterns containing silver on both sides of the window by selectively exposing/developing the silver salt emulsion layers.

The method may further include: after the forming of the first electrode patterns and the second electrode patterns, forming a protective layer covering the first electrode patterns.

The protective layer may be a hard coating layer, an optical clear adhesive, or an AR coating layer.

The hard coating layer may be made of acrylic, epoxy, urethane, or a combination thereof.

The method may further include: forming first wirings connected with the first electrode patterns on one surface of the window and; and forming second wirings connected with the second electrode patterns on the other surface of the window.

The first wirings may contain silver formed by selectively exposing/developing the silver salt emulsion layers and may be integrally formed with the first electrode patterns and the second wirings may contain silver formed by selectively exposing/developing the silver salt emulsion layers and may be integrally formed with the second electrode patterns.

The method may further include: disposing a control unit in the window, wherein the first wirings and the second wirings are connected with the control unit

The control unit may include: a first control unit disposed on one surface of the window; and a second control unit disposed on the other surface of the window, wherein the first wirings are connected with the first control unit, and the second wirings are connected with the second control unit.

The method may further include: after the forming of the first electrode patterns and the second electrode patterns, forming a printing part covering the first wirings.

At the forming of the silver salt emulsion layer, the silver salt emulsion layers may include a silver salt and a binder.

The silver salt may be silver halide.

At the forming of the optical filter layer(s), the optical filter layers may block an ultraviolet ray.

At the forming of the optical filter layer(s), the optical filter layers may block an Mine, an H-line, or a G-line of the ultraviolet ray.

At the forming of the optical filter layer(s), the optical filter layers may be made of UV blocking inorganic materials.

At the forming of the optical filter layer(s), the optical filter layers may be made of UV blocking organic materials.

At the forming of the first electrode patterns and the second electrode patterns, the silver salt emulsion layers may be exposed by using a proximity exposing device or a contact exposing device.

Sheet resistance of the first electrode pattern or sheet resistance of the second electrode pattern may be set to be 150 Ω/□ or less.

Sheet resistance of the first electrode pattern or sheet resistance of the second electrode pattern may be set to be 0.1 to 50 Ω/□.

A line width of the fine pattern of the first electrode pattern and a line width of the fine pattern of the second electrode pattern may be set to be 3 to 7 μm.

Transmittance of the touch panel may be set to be 85% or more.

An aperture ratio of the first electrode pattern or an aperture ratio of the second electrode pattern may be set to be 95% or more.

A thickness of the first electrode pattern or a thickness of the second electrode pattern may be set to be 2 μm or less.

A line width of the first wiring or a line width of the second wiring may be set to be 50 μm or less.

A pitch between the first wirings or a pitch between the second wirings may be set to be 50 μm or less.

### BRIEF DESCRIPTION OF THE DRAWINGS

The above and other objects, features and advantages of the present invention will be more clearly understood from the following detailed description taken in conjunction with the accompanying drawings, in which:

FIGS. 1A and 1B are cross-sectional views of a touch panel according to a preferred embodiment of the present invention;

FIGS. 2A and 2B are plan views of the touch panel from which a protective layer and a printing part are removed, according to the preferred embodiment of the present invention;

FIGS. 3A to 3D are enlarged plan views of fine patterns of first and second patterns shown in FIG. 1A;

FIGS. 4 to 6 are plan views of the first and second electrode patterns of the touch panel according to the preferred embodiment of the present invention; and

FIGS. 7 to 13 are cross-sectional views showing the process of a method for manufacturing a touch panel according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

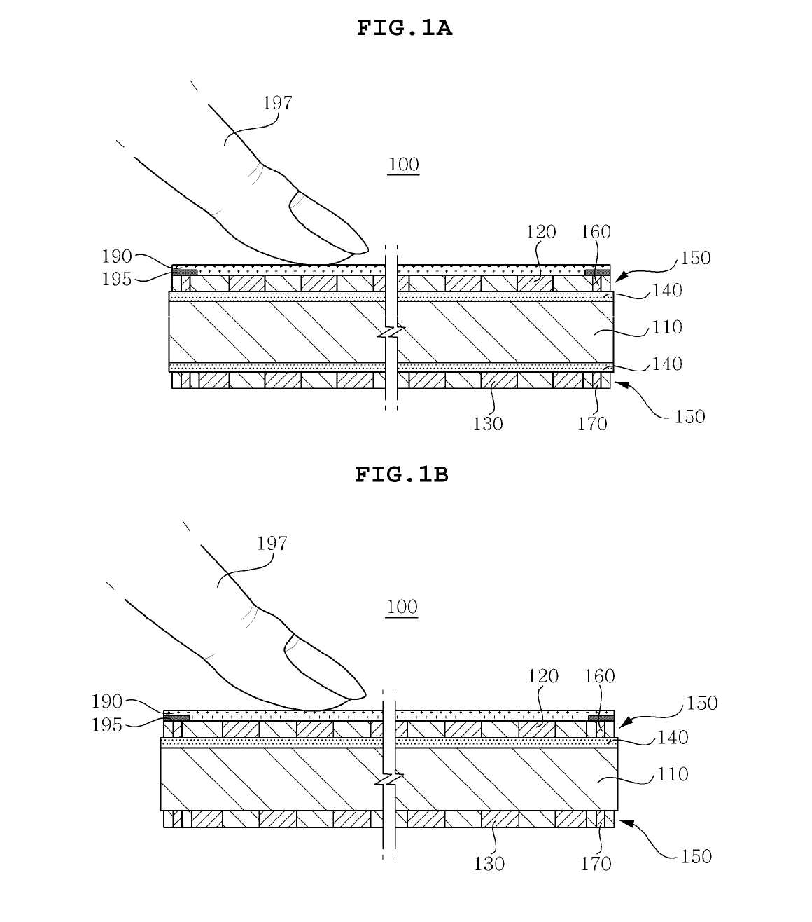

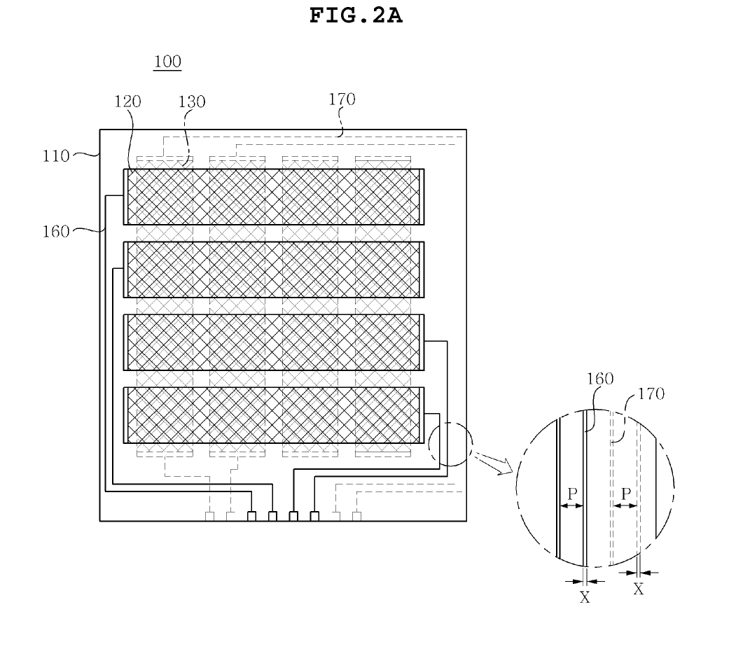

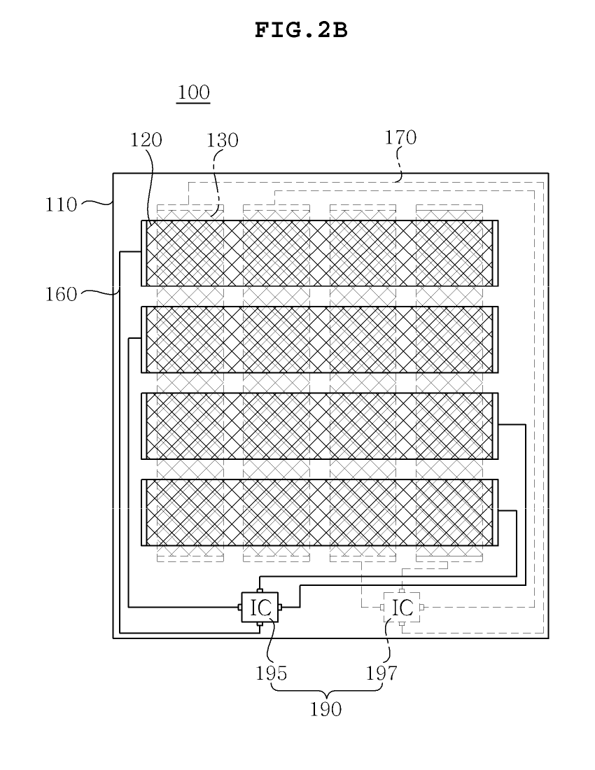

FIGS. 1A and 1B are cross-sectional views of a touch panel according to a preferred embodiment of the present invention and FIGS. 2A and 2B are plan views of the touch panel from which a protective layer and a printing part are removed, according to the preferred embodiment of the present invention.

As shown in FIGS. 1 and 2, a touch panel 100 according to the preferred embodiment of the present invention is configured to include: a window 110 that is a support disposed at an outermost side; first electrode patterns 120 containing silver formed by selectively exposing/developing silver salt emulsion layers 150 and formed on one surface of the window 110 as a fine pattern; second electrode patterns 130 containing silver formed by selectively exposing/developing silver salt emulsion layers 150 and formed on the other surface of the window 110 as a fine pattern; and optical filter layers 140 formed in at least one of between one surface of the window 110 and the first electrode patterns 120 and between the other surface of the window 110 and the second electrode patterns 130 to selectively block light.

The window 110, which serves to provide a region in which the first electrode patterns 120 and the second electrode patterns 130 are formed, is a support disposed on the outermost side of the touch panel 100. In this configuration, the window 110 needs to have support force capable of supporting the first electrode patterns 120 and the second electrode patterns 130 and transparency capable of allowing a user to recognize an image provided from an image display device. In consideration of the support force and the transparency described above, the window 110 may be made of polyethylene terephthalate (PET), polycarbonate (PC), poly methyl methacrylate (PMMA), polyethylene naphthalate (PEN), polyethersulfone (PES), a cyclic olefin polymer (COC), a triacetylcellulose (TAC) film, a polyvinyl alcohol (PVA) film, a polyimide (PI) film, polystyrene (PS), biaxially oriented polystyrene (BOPS; containing K resin), glass, tempered glass, or the like, but is not necessarily limited thereto.

Meanwhile, the first and second electrode patterns 120 and 130 are formed on both surfaces of the window 110. Therefore, a process of forming the electrode patterns on the separate window and then, bonding the electrode patterns to the window 110 may be omitted, thereby making it possible to simplify the manufacturing process and reducing the overall thickness of the touch panel 100.

The first electrode patterns 120 and the second electrode patterns 130 serve to generate signals at the time of a touch of a user to enable a control unit 190 to recognize touched coordinates. The first electrode patterns 120 are formed on one surface of the window 110 and the second electrode patterns 130 are formed on the other surface of the window 110. In this case, the fine patterns of the first electrode patterns 120 and the fine patterns of the second electrode patterns 130 are patterned by selectively exposing/developing the silver salt emulsion layers 150 (containing silver).

In addition, first wirings 160 and second wiring 170 serve to receive electrical signals by being connected to the first electrode patterns 120 and the second electrode patterns 130, respectively, wherein the first wirings 160 are formed on one surface of the window 110 and the second wirings 170 are formed on the other surface of the window 110. In this case, the first wirings 160 and the second wirings 170 are patterned by selectively exposing/developing the silver salt emulsion layers 150 (containing silver). In this case, the first wirings 160 are integrally formed with the first electrode patterns 120 and the second wirings 170 are integrally formed with the second electrode patterns 130. As such, the first wirings 160 are integrally formed with the first electrode patterns 120 and the second wirings 170 are integrally formed with the second electrode patterns 130, thereby making it possible to simplify the manufacturing process and shorten lead time. In addition, a bonding process of the first and second wirings 160 and 170 and the first and second electrode patterns 120 and 130 may be omitted, which may previously prevent occurrence of steps or a bonding defect between the first and second wirings 160 and 170 and the first and second electrode patterns 120 and 130. However, it is not necessarily to integrally form the first and second wirings 160 and 170 with the first and second electrode patterns 120 and 130 by exposing/developing the silver salt emulsion layers 150. Therefore, the first and second wirings 160 and 170 may be separately formed from the first and second electrode patterns 120 and 130 by using Ag paste, organic silver, conductive polymer, carbon black (containing CNT), metal oxide, metals, or the like.

In addition, as shown in FIG. 2B, the window 110 may be provided with a control unit 190 that is a kind of a controller. In this case, the first wirings 160 and the second wirings 170 are directly connected with the control unit 190 that is disposed on the window 110. As such, the first wirings 160 and the second wirings 170 may be directly connected with the control unit 190 that is disposed on the window 110, such that the conventional flexible printed circuit board may be omitted. For example, the control unit 190 may include a first control unit 195 that is disposed on one surface of the window 110 and a second control unit 197 that is disposed on the other surface of the window 110. In this case, the first wirings 160 are connected with the first control unit 195 and the second wirings 170 are connected with the second control unit 197.

Meanwhile, the silver salt emulsion layers 150 forming the first and second electrode patterns 120 and 130 and the first and second wirings 160 and 170 may include a silver salt 153 (see FIGS. 8A or 8B) and a binder 155. In this case, the silver salt 153 may be an inorganic silver salt such as silver halide (AgCl, AgBr, AgF, AgI), and the like, or acetic acid may be an organic silver salt. In addition, the binder 155 is to uniformly distribute the silver salt 153 and strengthen adhesion between the silver salt emulsion layers 150 and the optical filter layers 140 or between the silver salt emulsion layers 150 and the window 110 and a material of the binder 155 may be gelatin, polyvinyl alcohol (PVA), polyvinylpyrrolidone (PVP), polysaccharides such as starch, and the like, cellulose and derivatives thereof, polyethylene oxide, polyvinyl amine, chitosan, polylysine, polyacrylic acid, poly alginate, polyhyaluronic acid, carboxymethyl cellulose, and the like. The binder 155 has neutral, anionic, and cationic properties according to ionicity of a functional group.

In addition, the silver salt emulsion layers 150 may further include additives such as solvent, dye, or the like, in addition to the silver salt 153 and the binder 155. In detail, the solvent may be water, an organic solvent (for example, alcohols such as methanol, and the like, ketones such as acetone, and the like, amides such as formamide, and the like, sulfoxides such as dimethyl sulfoxide, and the like, esters such as ethyl acetate, and the like, ethers, and the like), ionic liquid, and a mixing solvent thereof

Meanwhile, sheet resistance of the first electrode patterns 120 or sheet resistance of the second electrode patterns 130 may be set to be 150 Ω/□ or less so as to be appropriate for the touch panel 100 by controlling a thickness thereof or controlling silver content of the silver salt emulsion layers 150. In more detail, the sheet resistance of the first and second electrode patterns 120 and 130 may be set to be 0.1 to 50 Ω/□. Herein, the reason why the sheet resistance of the first and second electrode patterns 120 and 130 is set to be 0.1 to 50 Ω/□ is that when the sheet resistance of the first and second electrode patterns 120 and 130 is 0.1 Ω/□ or less, an amount of silver salt 153 is too excessive and thus, transparency may be degraded and when the sheet resistance of the first and second patterns 120 and 130 is 50 Ω/□ or more, electric conductivity is low and thus, the utilization thereof may be degraded. However, the sheet resistance of the first and second electrode patterns 120 and 130 is not necessarily limited to the above numerical values.

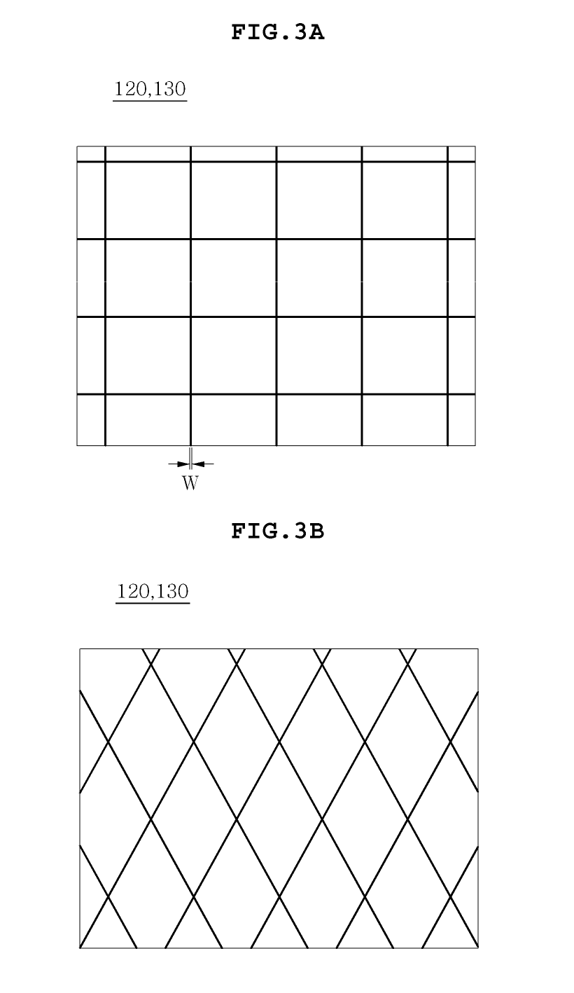

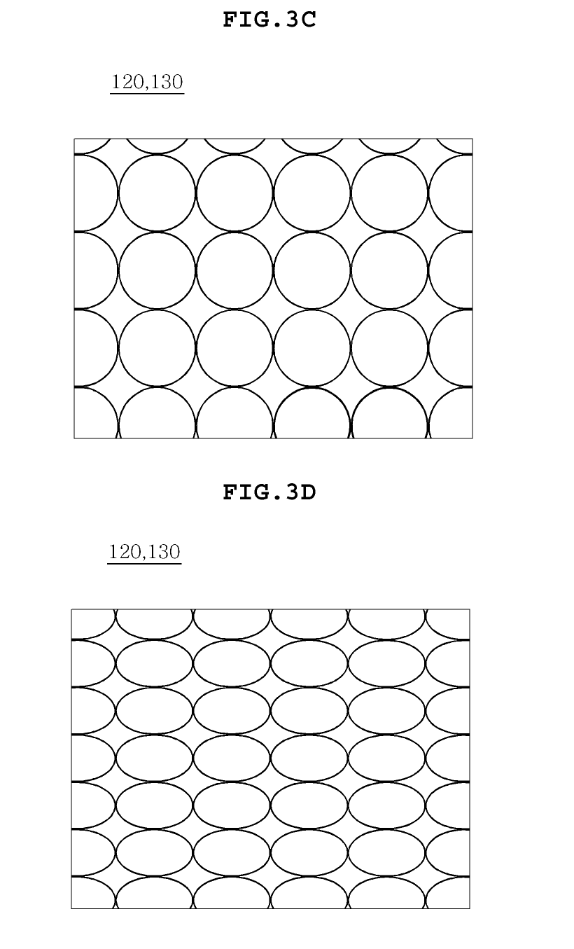

Further, FIGS. 3A to 3D are enlarged plan views of fine patterns of the first and second electrode patterns shown in FIG. 1A. Referring to FIGS. 3A to 3D, a configuration of the first electrode patterns 120 and the second electrode patterns 130 will be described in detail. As shown in FIG. 3A, a line width W of the fine patterns of the first and second electrode patterns 120 and 130 may be preferably set to be 3 μm or more so as to prevent the sheet resistance thereof from being excessively increased and may be preferably set to be 7 μm or less so as to prevent a user from visually identifying the patterns. As a result, the line widths W of the fine patterns of the first and second electrode patterns 120 and 130 may be preferably set to be 3 to 7 μm, but is not necessarily limited thereto.

Further, the fine patterns of the first electrode patterns 120 and the fine patterns of the second electrodes patterns 130 may have a mesh structure in which a rectangle (see FIG. 3A), a diamond (see FIG. 3B), a circle (see FIG. 3C), or an oval (see FIG. 3D) are repeated. That is, the fine patterns of the first and second electrode patterns 120 and 130 may have a mesh structure in which the fine patterns may intersect each other in a grid pattern.

Meanwhile, as shown in the enlarged view of FIG. 2A, a line width X and a pitch P (an interval between adjacent wirings) between the first wirings 160 and a pitch between the second wirings 170 may each be set to be 50 μm or less.

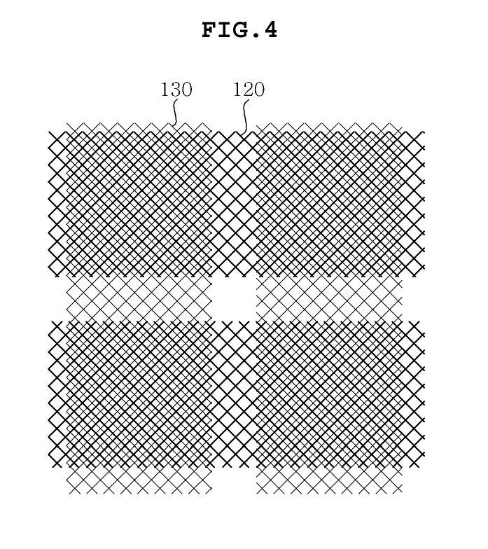

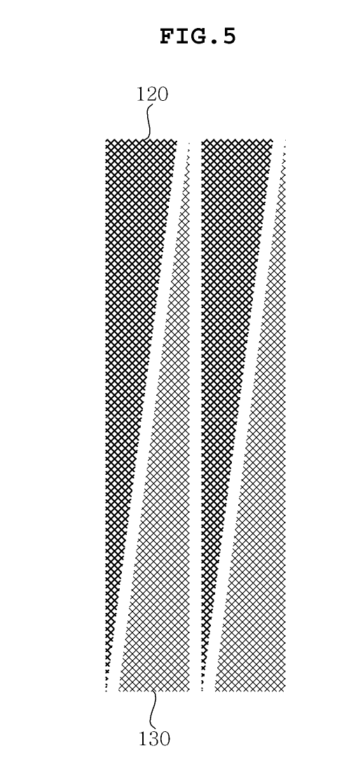

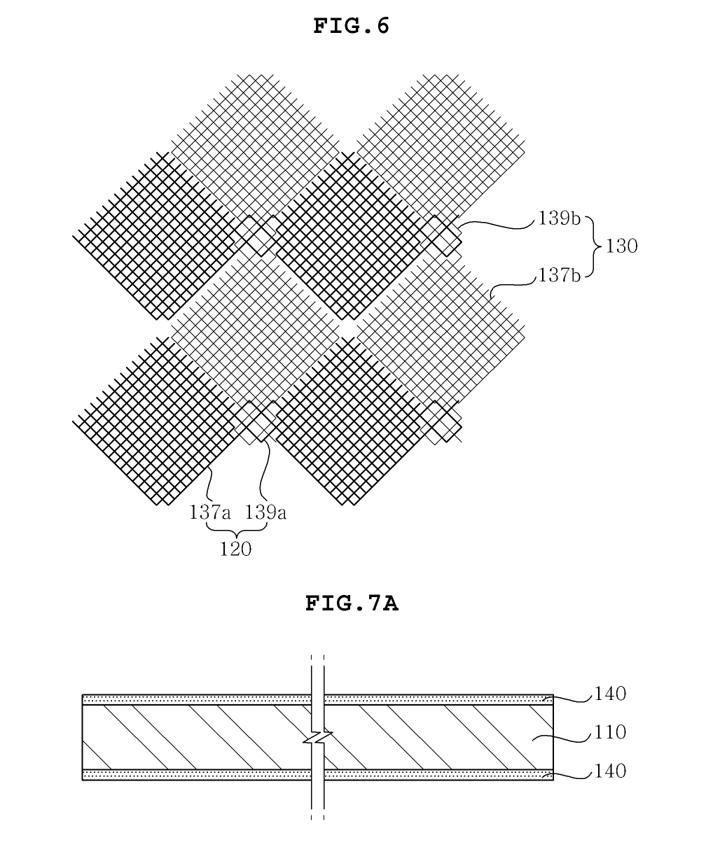

In addition, FIGS. 4 to 6 are plan views of the first and second electrode patterns of the touch panel according to the preferred embodiment of the present invention. As shown in FIGS. 4 to 6, the first electrode patterns 120 and the second electrode patterns 130 may be patterned in a bar type (see FIG. 4), a tooth type (see FIG. 5), or a diamond type (see FIG. 6).

In detail, the first electrode patterns 120 and the second electrode patterns 130 may be patterned in a bar type (see FIG. 4). In this case, the first electrode patterns 120 and the second electrode patterns 130 may be vertically formed to one another. In addition, if necessary, any one of the first electrode patterns 120 and the second electrode patterns 130 may be patterned in a bar type having a relatively large width and the other one thereof may be patterned in a bar type having a relatively smaller width (generally, configured defined by a bar type and a strip type).

Further, the first electrode patterns 120 and the second electrode patterns 130 may be patterned in a tooth type (see FIG. 5). In this case, the first electrode patterns 120 and the second electrode patterns 130 may be formed in a plurality of triangular types that are parallel with each other in one direction. Further, the first electrode patterns 120 may be inserted between the second electrode patterns 130 and the second patterns 130 may be inserted between the first electrode patterns 120 so that the first electrode patterns 120 and the second electrode patterns 130 do not overlap one another.

Further, the first electrode patterns 120 and the second electrode patterns 130 may be patterned in a diamond type (see FIG. 6). In this case, the first electrode patterns 120 and the second patterns 130 are configured to include sensing units 137a and 137b and connection parts 139a and 139b, wherein the first electrode patterns 120 and the second electrode patterns 130 may be vertically connected with one another through the connection parts 139a and 139b. Further, the sensing units 137a of the first electrode patterns 120 and the sensing units 137b of the second electrode patterns 130 may be disposed so as not to overlap one another.

However, as described above, patterning the first electrode patterns 120 and the second electrode patterns 130 in the bar type, the tooth type, or the diamond type is illustrated and therefore, is not limited thereto. The first electrode patterns 120 and the second electrode patterns 130 may be patterned in all the patterns known to those skilled in the art.

Further, the thickness of the first electrode pattern 120 or the thickness of the second electrode pattern 130 are not particularly limited, but may be set to be 10 μm or less so as to secure appropriate transmittance and may be preferably set to be 2 μm or less.

Meanwhile, the first electrode patterns 120 and the second electrode patterns 130 are formed by selectively exposing/developing the silver salt emulsion layers 150 and may use a proximity exposure device or a contact exposure device when exposing the silver salt emulsion layers 150 and the detailed description thereof will be described below in the manufacturing method.

In addition, the window 110 (see FIGS. 1A or 1B) is a support disposed on the outermost side of the touch panel 100 and therefore, may be provided with the protective layer 190 so as to prevent the first electrode pattern 120 formed on a top surface of the window 110 from directly contacting an input unit 197. That is, the protective layer 190 is formed on the first electrode patterns 120 so as to serve to protect the first electrode patterns 120. In this case, the protective layer 190 may be a hard coating layer, an optical clear adhesive (OCA), or an anti reflect (AR) coating layer, wherein the hard coating layer may be made of acrylic, epoxy, urethane, or a combination thereof

In addition, in order to cover the first wirings 160 or display a logo, or the like, the printing part 195 covering the first wirings 160 may be formed. Here, the printing part 195 may be formed by using screen printing or sputter. Among those, when the printing part 195 is formed by using the sputter, the thickness of the printing part 195 may be thinly formed up to a nanometer unit.

The optical filter layers 140 serve to selectively block (reflect or absorb) light to prevent the influence on the silver salt emulsion layers 150 that are formed on the surfaces of the window 110 facing each other even though the silver salt emulsion layers 150 formed on both surfaces of the window 110 are exposed. In this case, the optical filter layers 140 are formed in at least one of between one surface of the window 110 and the first electrode patterns 120 or between the other side of the window 110 and the second electrode patterns 130. That is, the optical filter layers 140 may be formed at both sides of the window 110 (see FIG. 1A) or formed at one side thereof (see FIG. 1B).

In detail, the optical filter layers 140 selectively block irradiated light when exposing the silver salt emulsion layers 150. Therefore, the optical filter layers 140 determine light to be blocked in consideration of light irradiated at the time of exposure. In this case, the light irradiated at the time of exposure has all the possible wavelengths, such as a visible ray, an ultraviolet ray, an X ray, and the like. When the ultraviolet ray (having a wavelength of about 10 to 397 nm) is irradiated at the time of exposure, the optical filter layers 140 are formed to selectively block the ultraviolet ray. In more detail, when an Mine (having a wavelength of 365 nm), an H-line (having a wavelength 405 nm), or a G-line (having a wavelength 436 nm) even in the ultraviolet ray at the time of exposure is irradiated, the optical filter layers 140 are formed to selectively block only the Mine, the H-line, or the G-line. As such, the optical filter layers 140 selectively block the light irradiated at the time of exposure to prevent the influence on the silver salt emulsion layers 150 formed on the surfaces of the window facing each other. In addition, the optical filter layers 140 transmit most light other than the light irradiated at the time of exposure and have substantially transparency, which results in preventing visibility of the touch panel 100 from being degraded.

Meanwhile, the optical filter layers 140 may be made of UV blocking inorganic materials or UV blocking organic materials. In this case, the UV blocking inorganic materials may be metal oxide such as indium tin oxide, titanium dioxide, and the like, and the UV blocking inorganic materials may be benzophenone, benzotriazole, salicylic acid, acrylonitrile, organic nickel compound, or the like. However, the aforementioned materials are by way of example only and therefore, the scope of the present invention is not limited thereto.

Meanwhile, as described above, the touch panel 100 that includes the window 110, the first electrode patterns 120, the second electrode patterns 130, and the optical filter layers 140 may preferably have transmittance of 85% or more so as to enable a user to recognize an image provided from an image display device. In addition, an aperture ratio of the first electrode pattern 120 and the second electrode pattern 130 may be controlled so that the transmittance of the touch panel 100 becomes 85% or more. In this case, the aperture ratio of the first electrode pattern 120 and the second electrode pattern 130 may be set to be 95% or more.

Further, the touch panel 100 according to the preferred embodiment of the present invention has the first electrode patterns 120 and the second electrode patterns 130 that are formed on both surfaces of the window 110, which may be used as a self capacitive type touch panel or a mutual capacitive type touch panel.

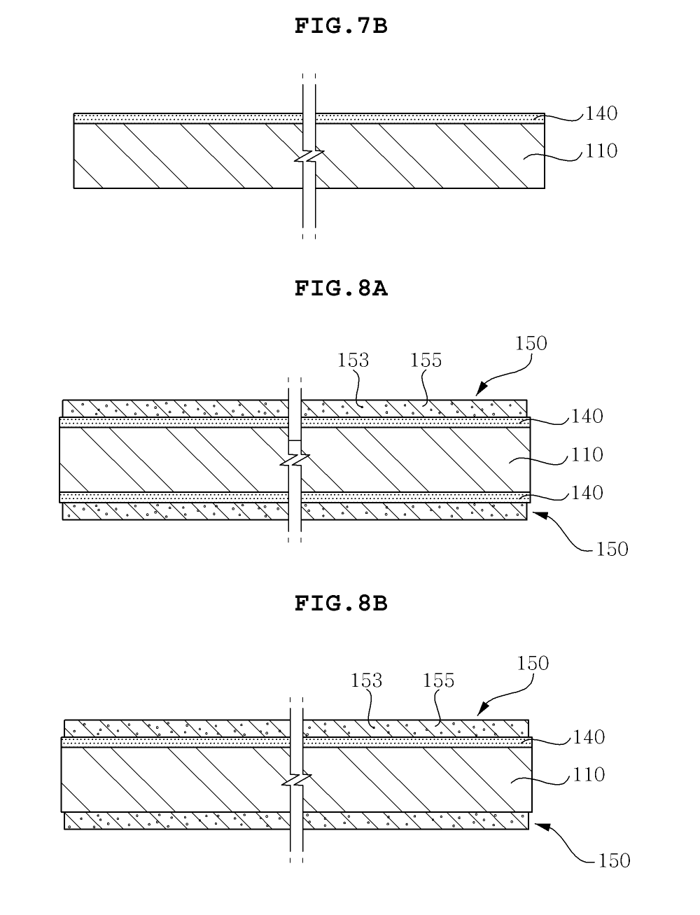

FIGS. 7 to 13 are cross-sectional views showing the process of a method for manufacturing a touch panel according to another preferred embodiment of the present invention.

As shown in FIGS. 7 to 13, a method for manufacturing a touch panel 100 according to the preferred embodiment of the present invention is configured to include: (A) forming the optical filter layer(s) on one surface or both surfaces of the window 110 that is the support disposed on the to outermost side so as to selectively block light; (B) forming the silver salt emulsion layer 150 on the optical filter layer 140 and the other surface of the window 110 when the optical filter layer 140 is formed on one surface of the window 110 and forming the silver salt emulsion layers 150 on the optical filter layers 140 when the optical filter layers 140 are formed on both surfaces of the window 110; and (C) forming the first electrode patterns 120 and the second electrode patterns 130 containing silver on both sides of the window 110 by selectively exposing/developing the silver salt emulsion layers 150.

First, as shown in FIG. 7A or 7B, the forming of the optical filter layers 140 on the window 110 is performed. In this case, the optical filter layers 140 serve to selectively block light when the silver salt emulsion layers 150 are exposed at the following step to prevent the influence on the silver salt emulsion layers 150 formed on the surfaces of the window facing each other. Therefore, the optical filter layers 140 determine the light to be blocked in consideration of the light used at the time of exposure. The light irradiated at the time of exposure has all the possible wavelengths, such as a visible ray, an ultraviolet ray, an X ray, and the like. When the ultraviolet ray (having a wavelength of about 10 to 397 nm) is irradiated at the time of exposure, the optical filter layers 140 are formed to selectively block the ultraviolet ray. In more detail, when an I-line (having a wavelength of 365 nm), an H-line (having a wavelength 405 nm), or a G-line (having a wavelength 436 nm) even in the ultraviolet ray at the time of exposure is irradiated, the optical filter layers 140 are formed to selectively block only the I-line, the H-line, or the G-line.

As such, in order for the optical filter layers 140 to block the ultraviolet ray, the I-line, the H-line, or the G-line, the optical filter layers 140 may be made of the UV blocking inorganic materials or the UV blocking organic materials. In detail, the UV blocking inorganic materials may be metal oxide such as indium tin oxide, titanium dioxide, and the like, and the UV blocking inorganic materials may be benzophenone, benzotriazole, salicylic acid, acrylonitrile, organic nickel compound, or the like. Meanwhile, when the optical filter layers 140 are made of the UV blocking inorganic materials, the optical filter layers 140 may be formed by sputtering, evaporation, and the like. Further, when the optical filter layer 140 is made of the UV blocking organic materials, the optical filter layers 140 may be formed by die casting, screen printing, gravure printing, off-set printing, bar coating, and the like.

Meanwhile, even though the optical filter layers 140 are formed only on at least one of one surface and the other surface of the window 110, the optical filter layers 140 can prevent the influence on the silver salt emulsion layers 150 formed on the surfaces of the window facing each other by blocking light when the silver salt emulsion layers 150 are exposed. Therefore, as shown in FIG. 7A, the optical filter layers 140 are not necessarily formed on both surfaces of the window 110, but as shown in FIG. 7B, may be formed only on at least one of one surface or the other surface of the window 110. Hereinafter, FIGS. 8A, 9A, 10A, 11A, 12A, and 13A show a configuration in which the optical filter layers 140 are formed on both surfaces of the window 110 and FIGS. 8B, 9B, 10B, 11B, 12B, and 13B show a configuration in which the optical filter layer 140 is formed on one surface of the window 110.

Next, as shown in FIG. 8A or 8B, the forming of the silver salt emulsion layers 150 is performed. At the aforementioned steps, when the optical filter layers 140 are formed on both surfaces of the window 110, the silver salt emulsion layers 150 are formed on the optical filter layers 140 formed on both surfaces of the window 110 (see FIG. 8A) and when the optical filter layer 140 is formed on one surface of the window 110, the silver salt emulsion layer 150 is formed on the optical filter layer 140 and the other surface of the window 110 (see FIG. 8B). Herein, the silver salt emulsion layers 150 include a silver salt 153 and a binder 155. In detail, the silver salt 153 may be an inorganic silver salt such as silver halide (AgCl, AgBr, AgF, AgI), and the like, or may be an organic silver salt such as acetic acid silver, and the like. In addition, the binder 155 may be gelatin, polyvinyl alcohol (PVA), polyvinylpyrrolidone (PVP), polysaccharides such as starch, and the like, cellulose and derivatives thereof, polyethylene oxide, polyvinyl amine, chitosan, polylysine, polyacrylic acid, poly alginate, polyhyaluronic acid, carboxy cellulose, and the like. For reference, the silver salt 150 are exaggeratedly shown to help understanding of the present invention and therefore, does not show an actual size or concentration, or the like. In addition, the silver salt emulsion layers 150 may further include additives such as solvent, dye, or the like, in addition to the silver salt 153 and the binder 155.

Meanwhile, the silver salt emulsion layer 150 may be formed by die casting, screen printing, gravure printing, off-set printing, bar coating, and the like. In addition, alter the silver salt emulsion layers 150 are formed, the silver salt emulsion layer 150 may be dried by hot-air drying, IR drying, natural drying, and the like.

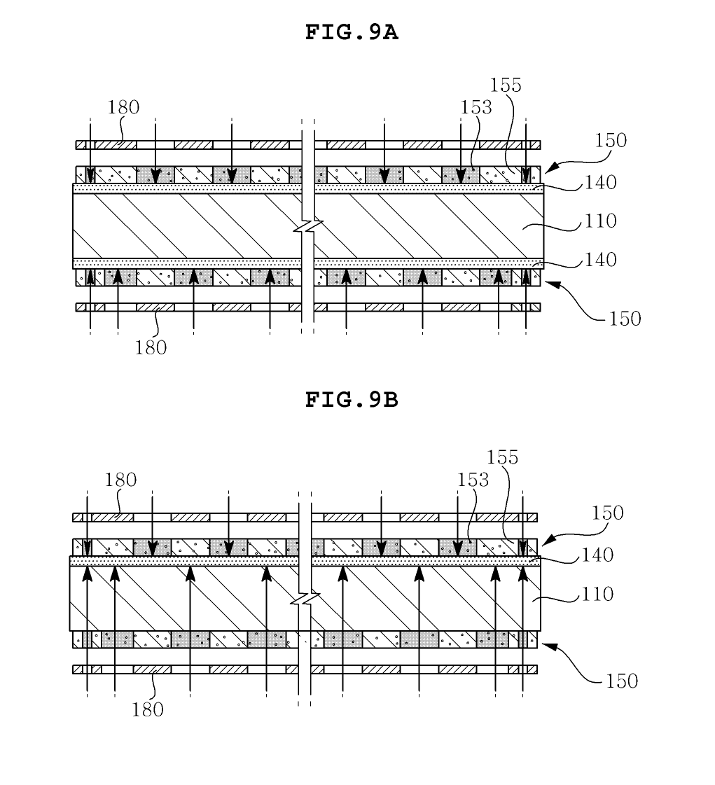

Next, as shown in FIGS. 9 to 11, the forming of the first electrode patterns 120 and the second electrode patterns 130 containing silver by selectively exposing/developing the silver salt emulsion layers 150 are performed. That is, the first electrode patterns 120 are formed at one side of the window 110 and the second electrode patterns 130 are formed at the other side thereof.

In detail, as shown in FIG. 9A or 9B, the selectively exposing of the silver salt emulsion layers 150 is performed. At the aforementioned steps, the silver salt emulsion layers 150 are formed at both sides of the window 110 and therefore, at the present step, the exposure is performed to both sides of the window 110. In this case, the exposure may be simultaneously performed at both sides of the window 110 or may be sequentially performed on one side thereof. Meanwhile, the light irradiated at the time of exposure has all the possible wavelengths such as a visible ray, an ultraviolet ray, an X ray, and the like, and may generally use the ultraviolet ray. In more detail, the exposure may be performed using the I-line (365 nm), the H-line (405 nm), or the G-line (436 nm) having relatively large intensity at the time of high pressure mercury discharge. Among others, the I-line having a relatively short wavelength may be selected so as to perform the precise exposure.

At the present step, after masks 180 are disposed at both sides of the window 110, when light is selectively irradiated to the silver salt emulsion layers 150, the silver salt 153 is photosensitized by photo energy in the silver salt emulsion layers 150 to which the light is irradiated, such that a minute silver nucleus defined by a so-called latent image is generated. As a result, the silver nucleus is generated in only the portion to which the light is irradiated through the exposure. As such, the portion to which light is irradiated is finally formed with the first electrode patterns 120, the first wirings 160, the second electrode patterns 130, and the second wirings 170. Therefore, at the present step, the exposure needs to be selectively performed in consideration of the first electrode patterns 120, the first wirings 160, the second electrode patterns 130, and the second wirings 170.

Meanwhile, as described above, even though the exposure is performed on both sides of the window 110, the optical filter layers 140 block the irradiated light at the time of exposure (see an arrow) and the silver salt emulsion layers 150 are not affected by light irradiated from the surfaces of the window 110 facing each other. Therefore, even though the fine patterns of the first electrode patterns 120 and the second electrode patterns 130 to be finally formed are different from each other, the silver salt emulsion layers 150 are not affected by the exposure performed on the surfaces of the window 110 facing each other at the time of exposure and therefore, the first electrode patterns 120 and the second electrode patterns 130 may be precisely formed.

In addition, when the silver salt emulsion layers 150 are exposed, the proximity exposure device or the contact exposure device may be used, wherein the proximity exposure device or the contact exposure device has a relatively shorter tact time, which leads to the improvement in productivity and mass production.

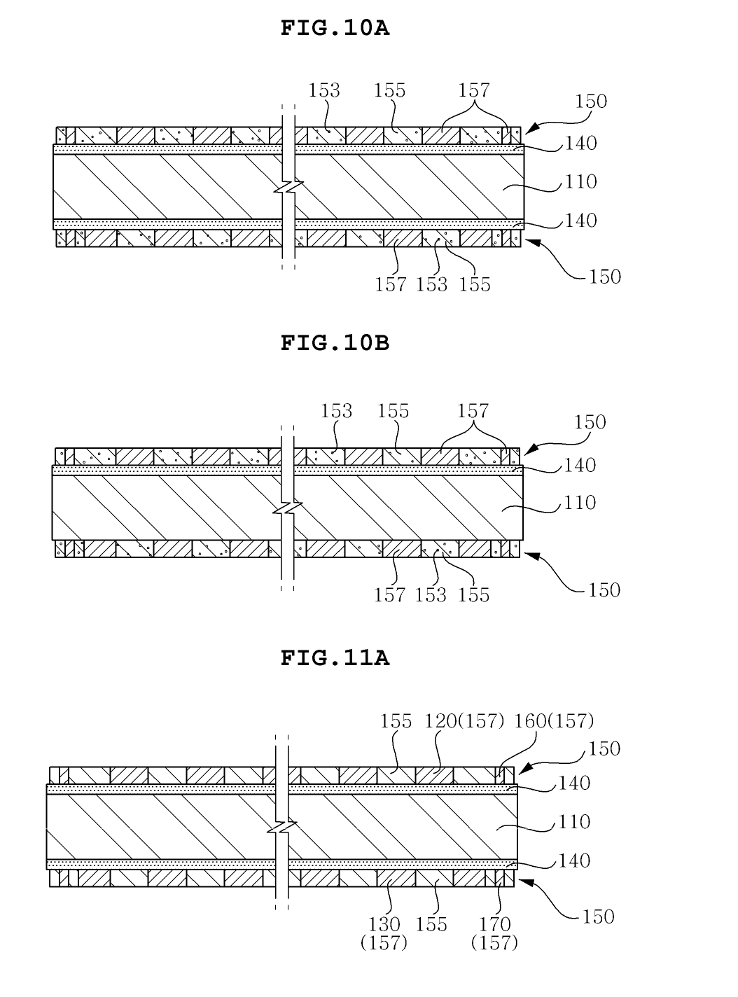

Next, as shown in FIG. 10A or 10B, the developing of the silver salt emulsion layers 150 is performed. The developing is to reduce a metal silver 157 by supplying a developer to the silver salt emulsion layers 150. In this case, silver ions provided from the silver salt 153 or the developer, are reduced to the metal silver 157 using the silver nucleus as a catalyst by a reducing agent in the developer. At the aforementioned steps, the silver nucleus is selectively generated only in the portion to which light is irradiated and therefore, at the present step, the metal silver 157 is selectively reduced only to the portion to which light is irradiated.

Meanwhile, as a method for supplying the developer to the silver salt emulsion layers 150, all the methods known to those skilled in the art may be used. For example, a method for dipping the silver salt emulsion layers 150 in the developer, a method for spraying the developer to the silver salt emulsion layers 150, a method for contacting the developer to the silver salt emulsion layers 150 in a vapor type, and the like, may supply the developer to the silver salt emulsion layers 150.

In addition, after the silver salt emulsion layer 150 is developed, the developer may be cleaned by water or may be removed by high pressure air.

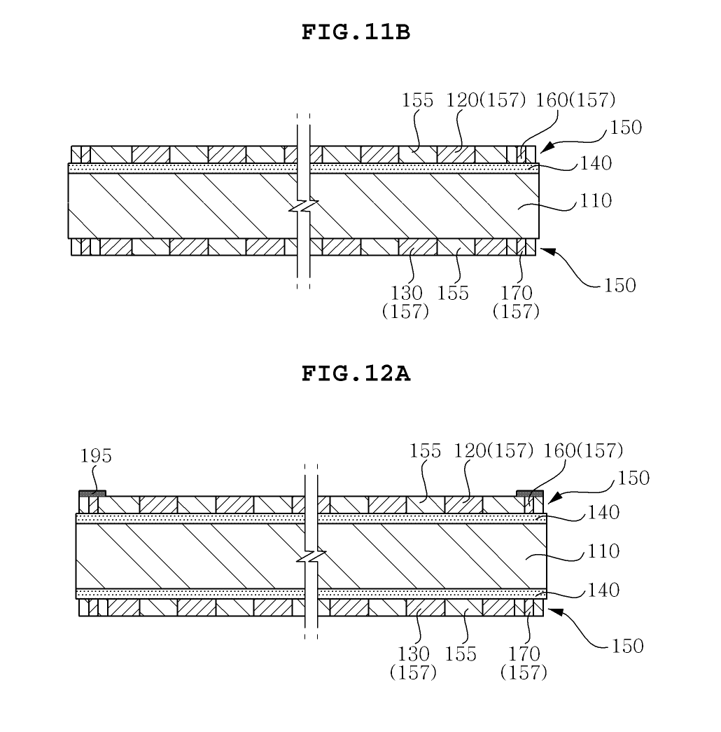

Next, as shown in FIG. 11 A or 11 B, a process of fixing the silver salt emulsion layers 150 is performed. Herein, the fixing process is to remove the silver salt 153 that is not reduced to silver by supplying a fixation fluid to the silver salt emulsion layer 150. As such, when the silver salt 153 that is not reduced to silver is removed, only the binder 155 such as gelatin, and the like, remains in the portion from which the silver salt 153 is removed.

As a result, the portion reduced to the metal silver 157 through the exposure/development in the silver salt emulsion layers 150 becomes the first electrode patterns 120, the first wirings 160, the second electrode patterns 130, and the second wirings 170 and the portion from which the silver salt 153 is removed through the fixation process remains only in the binder 155 and therefore, is transparent.

As described above, after the silver salt emulsion layers 150 are selectively exposed/developed, the first electrode patterns 120 and the first wirings 160 connected with the first electrode patterns 120 may be formed and the second electrode patterns 130 and the second wirings 170 connected with the second electrode patterns 130 may be formed, by the fixation process. In this case, the first wirings 160 are integrally formed with the first electrode patterns 120 and the second wirings 170 are integrally formed with the second electrode patterns 130.

However, it is not necessarily to integrally form the first and second wirings 160 and 170 with the first and second electrode patterns 120 and 130 by exposing/developing the silver salt emulsion layers 150. Therefore, the first and second wirings 160 and 170 may be separately formed from the first and second electrode patterns 120 and 130 by using Ag paste, organic silver, conductive polymer, carbon black (containing CNT), metal oxide, metals, or the like. In this case, the first and second wirings 160 and 170 may be printed using the screen printing method, the gravure printing method, the inkjet printing method, or the like.

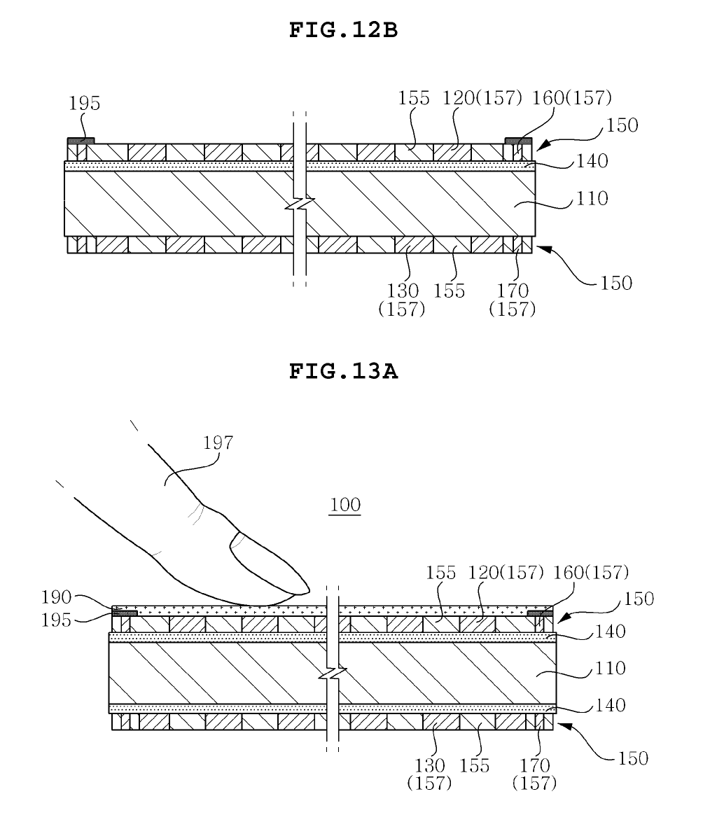

Next, as shown in FIG. 12A or 12B, a process of forming the printing parts 195 covering the first wirings 160 is performed. In this case, the printing parts 195 cover the first wirings 160 or display a logo, or the like, and may be formed by using screen printing or sputter.

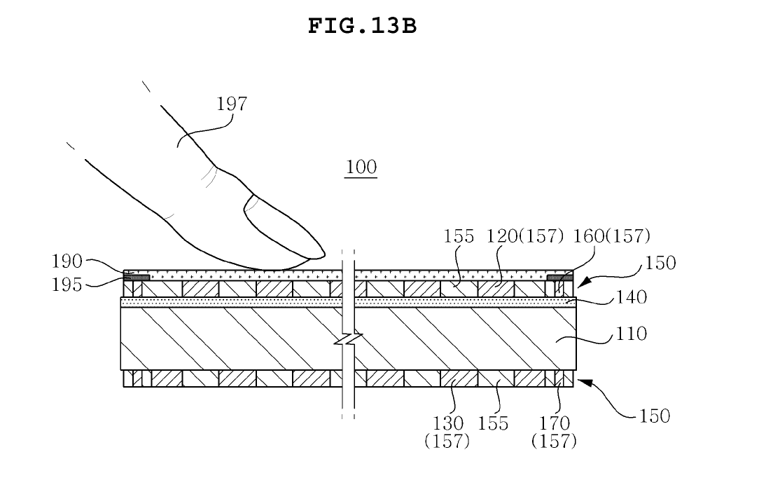

Next, as shown in FIG. 13A or 13B, the forming of the protective layer 190 on the first electrode patterns 120 is performed. In this case, the protective layer 190 is to protect the first electrode patterns 120 so that the first electrode patterns 120 do not directly contact the input unit 197 and may be a hard coating layer, an optical clear adhesive (OCA), or an anti reflect coating layer. In this case, the hard coating layer may be made of acrylic, epoxy, urethane, or a combination thereof. In addition, the protective layer 190 may be stacked on the first electrode patterns 120 in a film type and may be coated in a liquid state by the spin coating, or the like.

Meanwhile, as shown in FIG. 2B, the method for manufacturing a touch panel 100 according to the preferred embodiment of the present invention may further include the control unit 190 that is a kind of a controller on the window 110. In this case, the first wirings 160 and the second wirings 170 may be directly connected with the control unit 190 that is disposed on the window 110. As such, the first wirings 160 and the second wirings 170 may be directly connected with the control unit 190 that is disposed on the window 110, such that the conventional flexible printed circuit board may be omitted. For example, the control unit 190 may include the first control unit 195 that is disposed on one surface of the window 110 and the second control unit 197 that is disposed on the other surface of the window 110. In this case, the first wirings 160 are connected with the first control unit 195 and the second wirings 170 are connected with the second control unit 197.

The preferred embodiments of the present invention can implement the excellent electric conductivity while replacing ITO by forming the electrode patterns containing silver by exposing/developing the silver salt emulsion layers and can secure the excellent durability by withstanding the brittle fracture.

Further, the preferred embodiments of the present invention can adopt the optical filter layers to prevent the influence on the silver salt emulsion layers formed on the surfaces of the window facing each other even though the sliver salt emulsion layers formed on both surfaces of the window are subjected to the exposure.

In addition, the preferred embodiments of the present invention can directly form the electrode patterns on both surface of the window disposed at the outermost side of the touch panel to omit the process of forming the electrode patterns on the separate window and then, bonding the electrode patterns to the window, thereby making it possible to simplify the manufacturing process and reduce the overall thickness of the touch panel.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch panel, comprising:
a window that is a support disposed on an outermost side;
first electrode patterns containing silver formed by selectively exposing/developing silver salt emulsion layers and formed on one surface of the window as a fine pattern;
second electrode patterns containing silver formed by selectively exposing/developing silver salt emulsion layers and formed on the other surface of the window as a fine pattern; and
optical filter layers formed in at least one of between one surface of the window and the first electrode patterns and between the other surface of the window and the second electrode patterns to selectively block light.

2. The touch panel as set forth in claim 1, further comprising a protective layer covering the first electrode patterns.

3. The touch panel as set forth in claim 2, wherein the protective layer is a hard coating layer, an optical clear adhesive, or an AR coating layer.

4. The touch panel as set forth in claim 3, wherein the hard coating layer is made of acrylic, epoxy, urethane, or a combination thereof.

5. The touch panel as set forth in claim 1, further comprising:
first wirings formed on one surface of the window and connected with the first electrode patterns; and
second wirings formed on the other surface of the window and connected with the second electrode patterns.

6. The touch panel as set forth in claim 5, wherein the first wirings contain silver formed by selectively exposing/developing the silver salt emulsion layers and are integrally formed with the first electrode patterns, and
the second wirings contain silver formed by selectively exposing/developing the silver salt emulsion layers and are integrally formed with the second electrode patterns.

7. The touch panel as set forth in claim 5, further comprising: a control unit disposed on the window,
wherein the first wirings and the second wirings are connected with the control unit.

8. The touch panel as set forth in claim 7, wherein the control unit includes:
a first control unit disposed on one surface of the window; and
a second control unit disposed on the other surface of the window,
wherein the first wirings are connected with the first control unit, and
the second wirings are connected with the second control unit.

9. The touch panel as set forth in claim 5, further comprising: a printing part covering the first wirings.

10. The touch panel as set forth in claim 1, wherein the silver salt emulsion layers include a silver salt and a binder.

11. The touch panel as set forth in claim 10, wherein the silver salt is silver halide.

12. The touch panel as set forth in claim 1, wherein the optical filter layers block an ultraviolet ray.

13. The touch panel as set forth in claim 1, wherein the optical filter layers block an I-line, an H-line, or a G-line of the ultraviolet ray.

14. The touch panel as set forth in claim 1, wherein the optical filter layers are made of UV blocking inorganic materials.

15. The touch panel as set forth in claim 1, wherein the optical filter layers are made of UV blocking organic materials.

16. The touch panel as set forth in claim 1, wherein the silver salt emulsion layers are exposed by using a proximity exposing device or a contact exposing device.

17. The touch panel as set forth in claim 1, wherein sheet resistance of the first electrode pattern or sheet resistance of the second electrode pattern is set to be 150 Ω/□ or less.

18. The touch panel as set forth in claim 1, wherein sheet resistance of the first electrode pattern or sheet resistance of the second electrode pattern is set to be 0.1 to 50 Ω/□.

19. The touch panel as set forth in claim 1, wherein a line width of the fine pattern of the first electrode pattern and a line width of the fine pattern of the second electrode pattern are set to be 3 to 7 μm.

20. The touch panel as set forth in claim 1, wherein transmittance of the touch panel is set to be 85% or more.

21. The touch panel as set forth in claim 1, wherein an aperture ratio of the first electrode pattern or an aperture ratio of the second electrode pattern is set to be 95% or more.

22. The touch panel as set forth in claim 1, wherein a thickness of the first electrode pattern or a thickness of the second electrode pattern is set to be 2 μm or less.

23. The touch panel as set forth in claim 5, wherein a line width of the first wiring or a line width of the second wiring is set to be 50 μm or less.

24. The touch panel as set forth in claim 5, wherein a pitch between the first wirings or a pitch between the second wirings is set to be 50 μm or less.

25. A method for manufacturing a touch panel, comprising:
(A) forming optical filter layer(s) on one surface or both surfaces of a window that is a support disposed on an outermost side so as to selectively block light;
(B) forming a silver salt emulsion layer on the optical filter layer and the other surface of the window when the optical filter layer is formed on one surface of the window and forming the silver salt emulsion layers on the optical filter layers when the optical filter layers are formed on both surfaces of the window; and
(C) forming first electrode patterns and second electrode patterns containing silver on both sides of the window by selectively exposing/developing the silver salt emulsion layers.

26. The method as set forth in claim 25, further comprising: after the forming of the first electrode patterns and the second electrode patterns, forming a protective layer covering the first electrode patterns.

27. The method as set forth in claim 26, wherein the protective layer is a hard coating layer, an optical clear adhesive, or an AR coating layer.

28. The method as set forth in claim 27, wherein the hard coating layer is made of acrylic, epoxy, urethane, or a combination thereof.

29. The method as set forth in claim 25, further comprising:
forming first wirings connected with the first electrode patterns on one surface of the window; and
forming second wirings connected with the second electrode patterns on the other surface of the window.

30. The method as set forth in claim 29, wherein the first wirings contain silver formed by selectively exposing/developing the silver salt emulsion layers and are integrally formed with the first electrode patterns, and
the second wirings contain silver formed by selectively exposing/developing the silver salt emulsion layers and are integrally formed with the second electrode patterns.

31. The method as set forth in claim 29, further comprising: disposing a control unit in the window,
wherein the first wirings and the second wirings are connected with the control unit.

32. The method as set forth in claim 31, wherein the control unit includes:
a first control unit disposed on one surface of the window; and
a second control unit disposed on the other surface of the window,
wherein the first wirings are connected with the first control unit, and
the second wirings are connected with the second control unit.

33. The method as set forth in claim 29, further comprising: after the forming of the first electrode patterns and the second electrode patterns, forming a printing part covering the first wirings.

34. The method as set forth in claim 25, wherein at the forming of the silver salt emulsion layer, the silver salt emulsion layers include a silver salt and a binder.

35. The method as set forth in claim 34, wherein the silver salt is silver halide.

36. The method as set forth in claim 25, wherein at the forming of the optical filter layer(s), the optical filter layers block an ultraviolet ray.

37. The method as set forth in claim 25, wherein at the forming of the optical filter layer(s), the optical filter layers block an I-line, an H-line, or a G-line of the ultraviolet ray.

38. The method as set forth in claim 25, wherein at the forming of the optical filter layer(s), the optical filter layers are made of UV blocking inorganic materials.

39. The method as set forth in claim 25, wherein at the forming of the optical filter layer(s), the optical filter layers are made of UV blocking organic materials.

40. The method as set forth in claim 25, wherein at the forming of the first electrode patterns and the second electrode patterns, the silver salt emulsion layers are exposed by using a proximity exposing device or a contact exposing device.

41. The method as set forth in claim 25, wherein sheet resistance of the first electrode pattern or sheet resistance of the second electrode pattern is set to be 150 Ω/□ or less.

42. The method as set forth in claim 25, wherein sheet resistance of the first electrode pattern or sheet resistance of the second electrode pattern is set to be 0.1 to 50 Ω/□.

43. The method as set forth in claim 25, wherein a line width of the fine pattern of the first electrode pattern and a line width of the fine pattern of the second electrode pattern are set to be 3 to 7 μm.

44. The method as set forth in claim 25, wherein transmittance of the touch panel is set to be 85% or more.

45. The method as set forth in claim 25, wherein an aperture ratio of the first electrode pattern or an aperture ratio of the second electrode pattern is set to be 95% or more.

46. The method as set forth in claim 25, wherein a thickness of the first electrode pattern or a thickness of the second electrode pattern is set to be 2 μm or less.

47. The method as set forth in claim 29, wherein a line width of the first wiring or a line width of the second wiring is set to be 50 μm or less.

48. The method as set forth in claim 29, wherein a pitch between the first wirings or a pitch between the second wirings is set to be 50 μm or less.
